(19) United States
(12) Patent Application Publication
(10) Pub. No.: US 2025/0055212 A1
(43) Pub. Date: Feb. 13, 2025

(54) DUAL ENTRY CARD EDGE CONNECTOR

(71) Applicant: KYOCERA AVX Components Corporation, Fountain Inn, SC (US)

(72) Inventor: Brent Lybrand, Fountain Inn, SC (US)

(21) Appl. No.: 18/780,931

(22) Filed: Jul. 23, 2024

Related U.S. Application Data
(60) Provisional application No. 63/517,969, filed on Aug. 7, 2023.

(51) Int. Cl. H01R 12/72; H01R 12/73; H01R 13/115; H01R 43/20

(52) U.S. Cl. CPC H01R 12/721; H01R 12/737; H01R 13/115; H01R 43/205

(57) ABSTRACT

A card edge connector including a body including a first side and a second side, an open socket extending through the body from the first side to the second side, where the open socket includes an interior wall and a plurality of channels extending within the interior wall, and a plurality of electrical contacts positioned within the plurality of channels and extending into the open socket.

### CROSS REFERENCE TO RELATED APPLICATIONS

The present application claims priority to U.S. Provisional Application No. 63/517,969, filed Aug. 7, 2023, the contents of which are incorporated herein in its entirety.

### BACKGROUND

The present application relates generally to the field of electrical contacts and connectors, and more particularly to a type of card edge connector.

The following description is provided to assist the understanding of the reader. None of the information provided or references cited are admitted to being prior art.

Card edge connectors (or edge connectors) are embedded devices that mate with printed circuit boards (PCBs) to provide an electrical connection. Often, the card edge connectors mate multiple PCBs together. Various types of connectors are used for forming these electrical and mechanical connections between PCBs. These connectors can play a crucial role in achieving a design's size, cost, and performance constraints. Specifically, the necessary orientation for mating the PCBs and card edge connectors limits the overall design, including the required size to accommodate the PCB mating, and increases costs to accommodate different mating requirements for the PCBs. The size and cost constraints may subsequently limit the performance of the PCBs. Therefore, a card edge connector that can accommodate multiple mating orientations, optimizing the design choices for PCBs to achieve greater performance, is needed.

### SUMMARY

The assembly, system, and methods of this disclosure each have several innovative aspects, no single one of which is solely responsible for the desirable attributes disclosed herein.

In one aspect, a card edge connector is disclosed. The card edge connector includes a body including a first side and a second side, an open socket extending through the body from the first side to the second side, where the open socket includes an interior wall and a plurality of channels extending within the interior wall, and a plurality of electrical contacts positioned within the plurality of channels and extending into the open socket.

In another aspect, a card edge connector assembly is disclosed. The card edge connector assembly includes a card edge connector, where the card edge connector is mated to a printed circuit board (PCB). The PCB includes a plurality of electrical pads. The card edge connector is electrically coupled to the PCB. The electrical contacts of the card edge connector are configured to mate with the electrical pads of the PCB, electrically coupling the card edge connector and the PCB.

In another aspect, a card edge connector system is disclosed. The card edge connector system includes a first card edge connector assembly, including a body including a first side and a second side, an open socket extending through the body from the first side to the second side, wherein the open socket includes an interior wall and a plurality of channels extending within the interior wall, and a plurality of electrical contacts positioned within the plurality of channels and extending into the open socket. The card edge connector system further includes a card edge comprising a plurality of electrical pads configured to electrically couple with the plurality of electrical contacts of the card edge connector assembly, where a first end of the card edge is configured to be positioned within the open socket of the card edge connector assembly.

In yet another aspect, a method for creating a card edge connector assembly is disclosed. The method includes forming an open socket extending through a body from a first side to a second side, forming a plurality of channels extending within an interior wall of the open socket, providing a plurality of electrical contacts into the channels, where each electrical contact of the plurality of electrical contacts extends into the open socket, and shaping each electrical contact of the plurality of electrical contacts, where a first end extends from a respective channel to a position outside of and beyond a third side of the body, a second end positioned within the channel and behind the interior wall of the open socket, and a contact portion between the first end and the second end, where the contact portion extends from the channel into the open socket, and wherein the contact portion is angled in a first contact direction and a second contact direction.

### BRIEF DESCRIPTION OF THE DRAWINGS

FIG. 1 depicts an isometric view of a card edge connector in accordance with an illustrative embodiment.

FIG. 2 depicts an isometric view of a printed circuit board (PCB) with a hole configured for a body of the card edge connector to be positioned in accordance with an illustrative embodiment.

FIG. 3 depicts a top perspective view of the card edge connector assembly including the PCB, with a plurality of electrical contacts mated with the PCB in accordance with an illustrative embodiment.

FIG. 4 depicts a bottom perspective view of the card edge connector assembly including the PCB in accordance with an illustrative embodiment.

FIG. 5 depicts a cross-sectional view of the card edge connector assembly in accordance with an illustrative embodiment.

FIG. 6 depicts the card edge connector assembly with a card edge being inserted from a top side in accordance with an illustrative embodiment.

FIG. 7 depicts the card edge connector assembly with the card edge inserted into the open socket from the top side in accordance with an illustrative embodiment.

FIG. 8 depicts a cross-sectional view of the card edge connector assembly with the card edge inserted from the top side and mated with the plurality of electrical contacts within the open socket in accordance with an illustrative embodiment.

FIG. 9 depicts the card edge connector assembly with the card edge being inserted from the bottom side in accordance with an illustrative embodiment.

FIG. 10 depicts the card edge connector assembly with the card edge inserted into the open socket from the bottom side in accordance with an illustrative embodiment.

FIG. 11 depicts a cross-sectional view of the card edge connector assembly with the card edge inserted from the bottom side and mated with the plurality of electrical contacts within the open socket in accordance with an illustrative embodiment.

FIG. 12 depicts two card edge connector assemblies connected to a mating PCB, with a first card edge connector assembly mating with the mating PCB from the top side and a second card edge connector assembly mating with the mating PCB from the bottom side in accordance with an illustrative embodiment.

FIG. 13 depicts a flowchart illustrating a method for manufacturing/assembling the card edge connector assembly in accordance with an illustrative embodiment.

FIG. 14 depicts a flowchart illustrating a method for manufacturing/assembling the card edge connector assembly including a printed circuit board in accordance with an illustrative embodiment.

### DETAILED DESCRIPTION

Reference will now be made to various embodiments, one or more examples of which are illustrated in the figures. The embodiments are provided by way of explanation of the invention and are not meant as a limitation of the invention. For example, features illustrated or described as part of one embodiment may be used with another embodiment to yield still a further embodiment. It is intended that the present application encompass these, and other modifications and variations as come within the scope and spirit of the invention.

Disclosed herein is a dual entry card edge connector assembly, system, and method. In one embodiment, a card edge connector can be used for mating printed circuit boards (PCBs) in perpendicular orientations relative to each mated PCB. For example, a first PCB is mated to a second PCB via a card edge connector, where the first PCB and the second PCB are oriented perpendicularly to one another. The card edge connector includes a body and an open socket, extending through the body. Within the body are electrical contacts, partially extending into the open socket for electrical coupling with electrical pads on a PCB when the PCB is inserted into the open socket. Because the open socket extends through the body, the PCB can be inserted from either of opposite sides (e.g., either the top or the bottom) of the card edge connector.

In another embodiment, a card edge connector assembly includes a card edge connector and a PCB. The PCB is electrically coupled with the card edge connector via the electrical contacts of the card edge connector and electrical pads on the PCB. Further, the PCB includes a hole, extending through the PCB, configured for at least part of the card edge connector to fit into. The card edge connector electrically couples with the PCB and part of the body of the card edge connector rests on the surface of the PCB. The card edge connector assembly provides access to the open socket of the card edge connector assembly from above and below the card edge connector assembly.

In another embodiment, a card edge connector system includes a card edge connector assembly and a daughterboard PCB. The card edge connector assembly may be any one of the card edge connector assemblies disclosed herein. The daughterboard PCB may be a printed circuit board or other type of electronic component. The card edge connector assembly provides access to the open socket of the card edge connector assembly from above and below the card edge connector assembly. This accessibility allows a daughterboard PCB to be inserted into the open socket from either a first or second side (e.g., the top or the bottom) of the card edge connector. The multi-directional insertion capabilities allow the daughterboard PCB to be inserted into the card edge connector assembly, electrically coupling with the PCB through the electrical contacts, from a direction determined by the daughterboard PCB, not limited by the connector. In other words, the design of the system adapts to where the daughterboard PCB is positioned, optimizing design choices, lowering costs, and increasing performance.

In another embodiment, multiple PCBs can be mated with the inserted daughterboard PCB in a perpendicular orientation relative to each PCB, where the PCBs face the same direction (i.e., the electrical pads on the PCBs are pointed upwards). The novel design of the card edge connector system provides multiple orientations for mating PCBs and daughterboard PCBs. The card edge connector system allows insertion of the daughterboard PCB from multiple directions (i.e., from the top or bottom of the connector), so the PCBs can be mated in an optimal orientation, based on the design needs of a given application. Without the novel design, existing systems are limited in orientation, as the daughterboard PCB must be inserted into a connector from one direction. The card edge connector, card edge connector assembly and/or card edge connector system is applicable across any industry using electronics, specifically those electronics utilizing printed circuit boards. Specifically, the illustrated embodiments highlight any application where printed circuit boards need to be mated together, from both directions. Because the card edge connector provides insertion of the daughterboard PCB from multiple directions, the design choices (for any application) are not limited by the connector, which increases the number of potential applications for the connector, optimizes the design, decreases the complexity of the design and assembly, lowers costs, and increases the performance of the design.

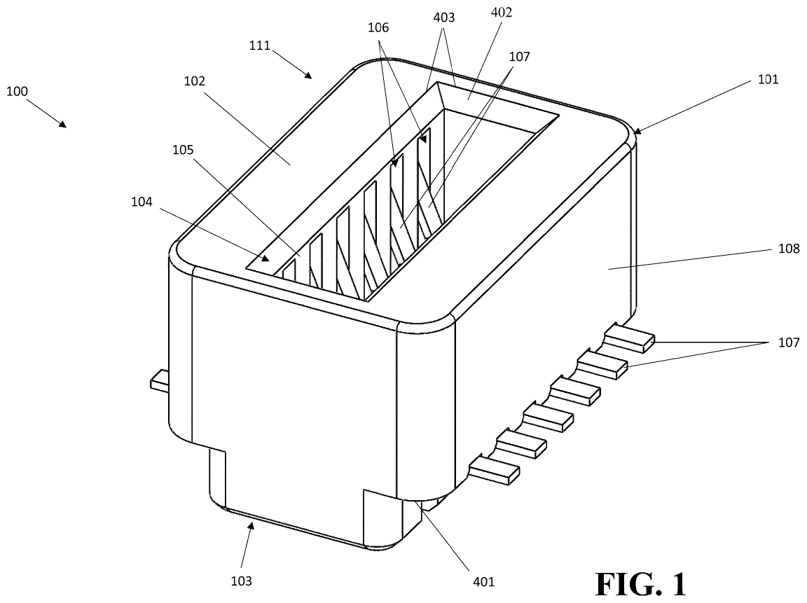

With reference to FIG. 1, the illustrated embodiment shows a card edge connector 111. The card edge connector includes a body 101 having a first side 102 and a second side 103 and an open socket 104 extending through the body 101 from the first side 102 to the second side 103. The open socket 104 extends entirely through the body 101. The open socket 104 includes an interior wall 105 having a plurality of channels 106 formed therein and extending within the interior wall 105. The card edge connector 111 further includes a plurality of electrical contacts 107 positioned at least partially within the channels 106, where each of the plurality of electrical contacts 107 extends into the open socket 104. The plurality of electrical contacts 107 can consist of 2, 3, 4, 5, or more electrical contacts. For example, in the illustrated embodiment, the plurality of electrical contacts 107 consists of 12 electrical contacts. In some embodiments, the electrical contacts 107 also extend from the channels 106 outside the body 101. Each of the electrical contacts of the plurality of electrical contacts 107 extend from a respective channel 106 to a position outside of and beyond a third side 108 of the body 101. In some embodiments, the third side 108 of the body 101 is a side of the body 101. In some embodiments, the first side 102 and the second side 103 are the top and bottom sides of the body 101.

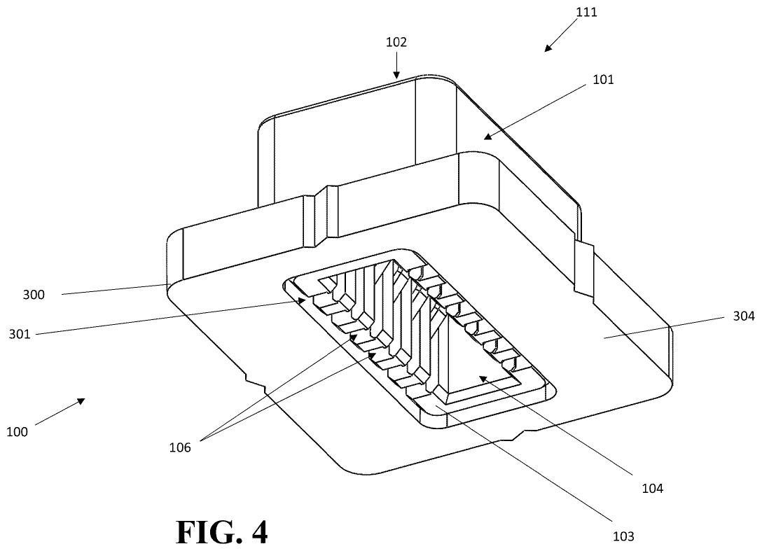

With continued reference to FIG. 1, in the illustrated embodiment, the open socket 104 includes edges 402 around a perimeter of the open socket 403 on the first side 102. In the illustrated embodiment, the edges 402 are beveled. The beveled edges facilitate insertion of a card edge into the open socket. In some embodiments, the open socket 104 includes edge 402 around a perimeter of the open socket 403 on the second side 103 (see FIG. 4). In some embodiments, the open socket 104 includes edges 402 around a perimeter of the open socket 403 on both the first side 102 and the second side 103 (see FIGS. 1 and 4). In alternative embodiments, the edges 402 may include features other than beveling to facilitate insertion of the card edge into the open socket. For example, the edges 402 around the perimeter of the open socket 403 may be angled differently or may not be angled at all (i.e., straight edges, rounded edges, chamfered edges).

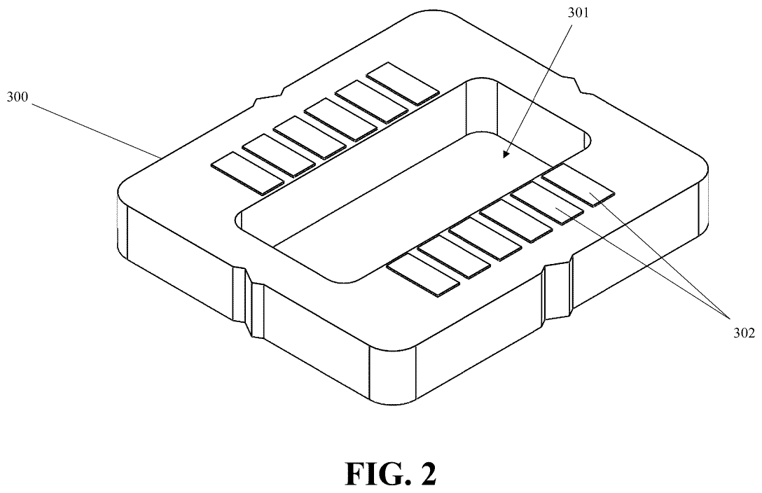

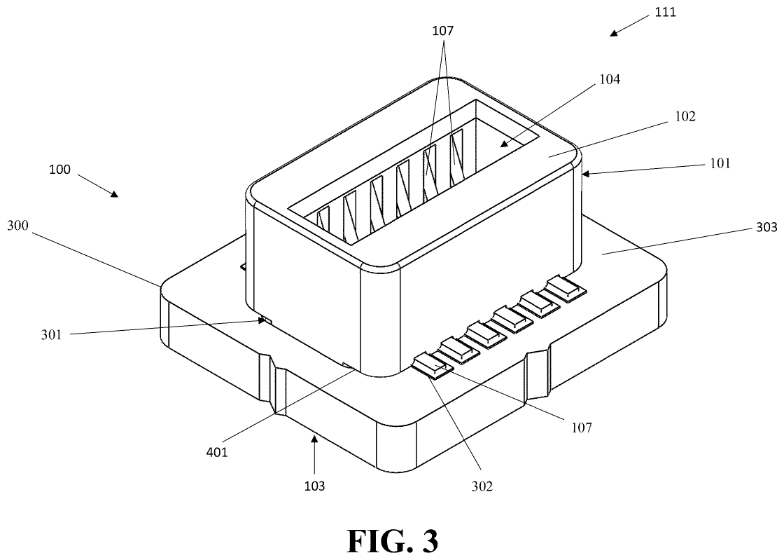

With continued reference to FIG. 1, in some embodiments, a card edge connector assembly 100 includes the card edge connector 111. The card edge connector 111 may be designed with alternative dimensions of the connector and mating printed circuit board configuration to those depicted in the figures herein. In some embodiments, the card edge connector 111 may have a larger height, to accommodate mating with a thicker PCB. In some embodiments, the card edge connector 111 may be longer, to accommodate more electrical contacts for mating with either the PCB or the card edge. In some embodiments, the body 101 of the card edge connector 111 may be shaped differently to configure with the PCB (see FIGS. 2 and 3 for more detail). In other words, the card edge connector may be designed according to a variety of different performance needs, such as: voltage ratings, current ratings, resistances, operating temperatures, and/or mating PCB size and configuration.

With reference to FIGS. 2, 3, and 4, the illustrated embodiments show aspects of the card edge connector 111 configured to mate with a PCB 300 (also referred to as a motherboard), forming a card edge connector assembly 100. The PCB 300 is configured to mate with the card edge connector assembly 100. In some embodiments, the body 101 of the card edge connector 111 is configured to extend, at least partially, into a hole 301 of the PCB. In the illustrated embodiments, the card edge connector 111 and the PCB 300 are mated, electrically coupling them together. In the illustrated embodiments, the PCB 300 and the card edge connector 111 are configured to provide access to the open socket 104 from the first side 102. In the illustrated embodiments, the PCB 300 and the card edge connector 111 are configured to provide access to the open socket 104 from the second side 103. In other words, the open socket is also accessible from underneath the PCB (see FIG. 4), in addition to being accessible from above the PCB.

With reference to FIG. 2, the illustrated embodiment shows a printed circuit board (PCB) 300 with a hole 301 configured to receive a body 101 of the card edge connector 111. The hole 301 extends through the PCB 300. In the illustrated embodiment, the hole 301 is rectangular shaped with rounded edges. In some embodiments, the hole 301 may be shaped differently (i.e., circularly shaped, rectangular without rounded edges). In the illustrated embodiment, the hole 301 is shaped for at least part of the body 101 of the card edge connector 111 to fit into.

With reference to FIG. 3, the illustrated embodiment shows the card edge connector 111 mated with a PCB 300. In the illustrated embodiment, the card edge connector assembly 100 includes the card edge connector 11 and the PCB 300. In the illustrated embodiment, the body 101 of the card edge connector 111 is partially positioned within the hole 301 of the PCB 300. In some embodiments, the body 101 of the card edge connector 111 includes shoulders 401. The shoulders 401 are positioned adjacent to a surface of the PCB 300. In some embodiments, the shoulders 401 are positioned adjacent to a top surface 303 of the PCB 300 while at least part of the body 101 is positioned within the hole 301 of the PCB 300. In other words, the shoulders on the body stop the body from going all the way through the hole of the PCB, allowing the body to rest on a surface of the PCB when mated. The portions of the body resting on the surface of the PCB are referred to as the shoulders. For example, in the illustrated embodiment, the body is T-shaped, with a wider section of the body on top, and a narrower section of the body on bottom, so the narrow section extends into the hole of the PCB, and the wider section of the body resting on a surface of the PCB. In some embodiments, the body is shaped differently. The body should be shaped to at least partially fit into the hole of the PCB.

With reference to FIG. 4, the hole 301 of the PCB 300 and the body 101 of the card edge connector 111 are configured to provide access to the open socket 104 from the second side 103. In other words, the hole provides access to the open socket from underneath the PCB.

With continued reference to FIG. 4, in the illustrated embodiment, the body 101 partially extends into the hole 301 of the PCB 300, however, the body 101 does not extend past a bottom surface 304 of the PCB 300. In some embodiments, the second side 103 of the card edge connector 100 is flush with the bottom surface 304 of the PCB 300. In other words, the second side of the card edge connector does not extend past the bottom surface of the PCB 300. The body is configured so the portion of the body extending through the hole of the PCB 300 has a smaller height than a thickness of the PCB. For example, this may be so the PCB 300 can rest flatly on another surface. In still another embodiment, a relatively thinner PCB may be used for PCB 300 and the body 101 may extend beyond the bottom surface of the PCB 300.

With reference to FIGS. 2 and 3, in the illustrated embodiments, the PCB 300 includes electrical pads 302. In the illustrated embodiments, the PCB includes electrical pads 302 on one side of the PCB 300 (i.e., on the top surface). In some embodiments, the PCB 300 may include electrical pads 302 on more than one side of the PCB 300. For example, the PCB 300 may include the plurality of electrical pads 302 on both sides. In the illustrated embodiments, the electrical pads 302 are evenly spaced. In some embodiments, the electrical pads 302 may be spaced differently (i.e., further apart or in a staggered pattern). In the illustrated embodiments, the electrical pads 302 are shaped rectangularly. In some embodiments, the electrical pads may be shaped differently (i.e., circular, squarely, ovular, hexagonal). In some embodiments, the PCB 300 has 2, 3, 4, 5, or more electrical pads 302. For example, in the illustrated embodiment, the PCB 300 has 12 electrical pads 302. The number of electrical pads 302 on the PCB 300 should match the number of electrical contacts 107 of the card edge connector 111. In some embodiments, the number of electrical pads 302 and the number of electrical contacts 107 may not match.

With reference to FIG. 3, the illustrated embodiments show the card edge connector 111 mated with the PCB 300. The electrical pads 302 on the PCB 300 are mated with the electrical contacts 107 of the card edge connector. In the illustrated embodiment, the electrical contacts 107 are similarly shaped and spaced to easily mate with the electrical pads 302 on the PCB 300. In the illustrated embodiment, the electrical contacts 107 are mated to the electrical pads 302 by soldering them together for electrical coupling. In some embodiments, the electrical contacts 107 and the electrical pads 302 are not mated by soldering. For example, in some embodiments, the electrical contacts 107 and the electrical pads 302 are mated by at least one of conductive adhesives, crimping, welding, mechanical fastening, brazing, clamping, or press fitting.

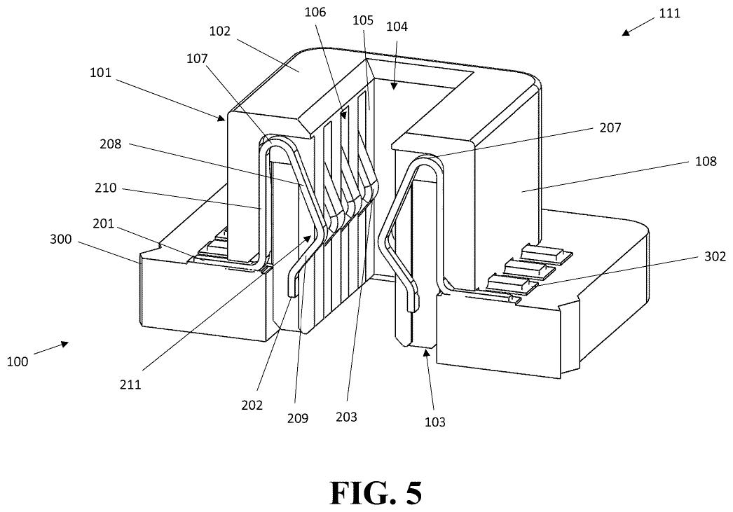

With reference to FIG. 5, the illustrated embodiment shows the interior of the open socket 104 of the card edge connector assembly 100. In the illustrated embodiment, the card edge connector assembly 100 includes the card edge connector 111 mated to the PCB 300. In the illustrated embodiment, the card edge connector assembly 100 includes the body 101, having a first side 102 and a second side 103, an open socket 104, where the open socket 104 includes the interior wall 105, where the channels 106 extend within the interior wall 105 for the plurality of electrical contacts 107 to be positioned, with the electrical contacts 107 extending into the open socket 104.

With continued reference to FIG. 5, in the illustrated embodiment, each of electrical contact of the plurality of electrical contacts 107 include a first end 201, a second end 202, and a contact portion 203. The first end of the electrical contact 201 extends from the channel 106 to a position outside the body 101 and beyond a third side 108 of the body 101 of the card edge connector assembly 100. The second end of the electrical contact 202 is positioned within the channel 106, behind the interior wall 105 of the open socket 104. The second end 202 being positioned within the interior wall 105 helps keep the electrical contact 107 in place during use. In some embodiments, the first end of the electrical contact 201 is mated with the electrical pads 302 on the PCB 300, electrically coupling the electrical contacts 107 and the PCB 300. In the illustrated embodiment, the contact portion of the electrical contact 203 is positioned within the open socket 104. In the illustrated embodiment, the contact portion 203 is between the first end 201 and the second end 202. The contact portion 203 extends from the channel 106 into the open socket 104.

With continued reference to FIG. 5, in the illustrated embodiment, the electrical contact 107 includes a first contact section 208 extending at a first angle in a first direction toward the first side of the body 102, and a second contact section 209 extending in a second direction toward the second side of the body 103. The angling of the first and second contact sections 208, 209 away from a point of maximum extent of the contact portion 203 into the open socket 104 facilitates insertion and mating of a PCB 500 (also referred to as a daughterboard) from either the first side of the body 102 or the second side of the body 103. In other words, the electrical contact having a contact portion that with angles in two, opposite directions provides electrical coupling of the card edge and the card edge connector assembly when a card edge is inserted into the open socket from either the top or the bottom of the card edge connector assembly.

With continued reference to FIG. 5, in the illustrated embodiment, each electrical contact of the plurality of electrical contacts 107 has a shape that is uniform. In some embodiments, the shape of the electrical contacts differs. In the illustrated embodiment, each electrical contact of the plurality of electrical contacts 107 includes a U-shaped portion 207, positioned between the contact portion 203 and the first end 201. The U-shaped portion 207 is positioned within the channel 106. In the illustrated embodiment, each electrical contact of the plurality of electrical contacts 107 further includes a leg portion 210 extending between the U-shaped portion 207 and the first end 201, where the first end 201 extends perpendicularly from the leg portion 210. The first end 201 extends to a position outside of and beyond the third side 108 of the body 101. In the illustrated embodiment, each electrical contact of the plurality of electrical contacts 107 further includes the contact portion 203 which includes a bent portion 211 connecting the first contact section 208 extending between the second end 202 and the contact portion 203 and the second contact section 209 extending between the contact portion 203 and the U-shaped portion 210. In the illustrated embodiment, the shape of the contact portion facilitates mating with a card edge when the card edge is inserted into the open socket from either the first side or the second side of the card edge connector assembly.

With continued reference to FIG. 5, in some embodiments, each electrical contact of the plurality of electrical contacts 107 may change shape during use (i.e., when mating with the card edge, when mated with the electrical pads of the PCB). In alternative embodiments, each electrical contact of the plurality of electrical contacts 107 may include a different shape. In alternative embodiments, one or more of the first contact section, the second contact section, the contact portion, the leg portion, and the U-shaped portion of each electrical contact of the plurality of electrical contacts 107 may include a different shape.

With continued reference to FIG. 5, in the illustrated embodiment the channel 106 extends from the outside of the body 101 through the interior wall 105 of the open socket 104. In some embodiments, the channel 106 extends outside the body 101 in perpendicular to the third side 108 of the body 101. In some embodiments, the channel 106 extends outside the body 101 parallel to the third side 108 of the body 101. In some embodiments, the card edge connector assembly 100 includes 2, 3, 4, 5, or more channels 106. For example, in the illustrated embodiment, the card edge connector assembly 100 has 12 channels 106. In some embodiments, the number of channels 106 is equal to the number of electrical contacts 107. In the illustrated embodiment, the channel 106 is configured for the electrical contact 107 to fit into the channel 106. The electrical contact 107 is positioned within the channel 106 without fastening the electrical contact 107 into the channel 106. In the illustrated embodiment, the channel 106 consists of extra space for the electrical contact 107 to move. When a card edge is inserted into the open socket, and mates with the electrical contacts, the electrical contacts may move within the channel. In other words, contact between the card edge and the electrical contact may push the electrical contact backwards in the channel, so the channel is designed with extra room for the electrical contact to move or bend backwards within the channel.

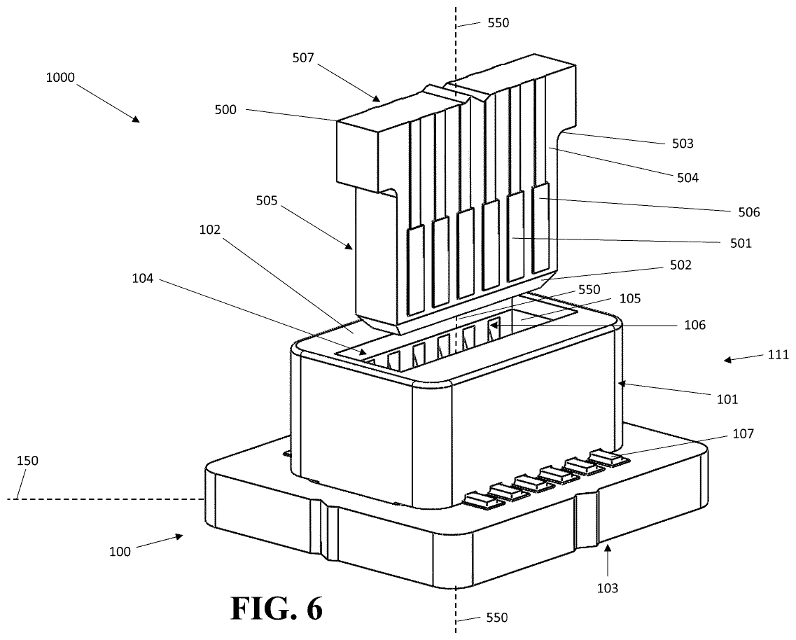

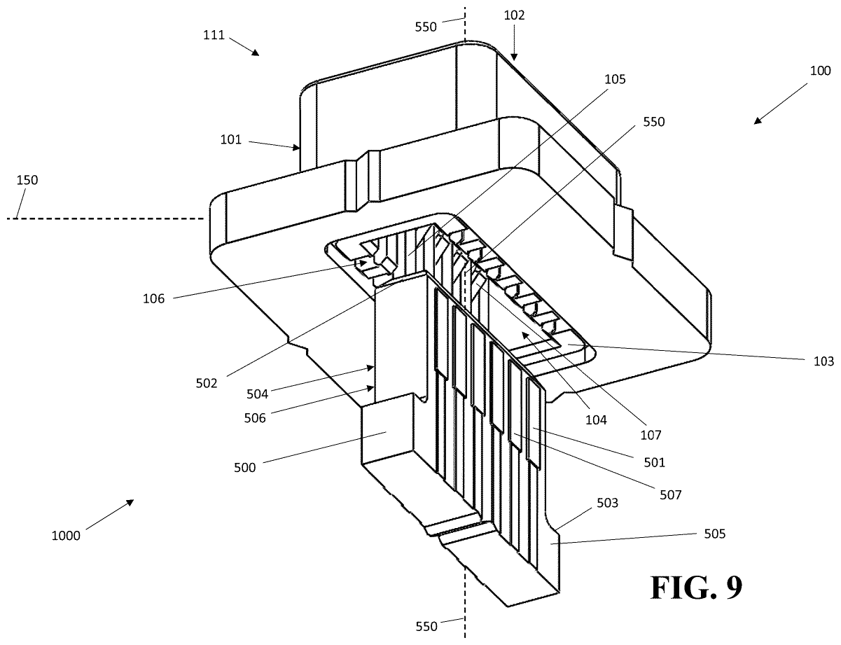

With reference to FIGS. 6-11, the illustrated embodiments show a card edge connector assembly 100 configured to mate with a PCB 500, forming a card edge connector system 1000. FIGS. 6-8 show the PCB 500 being inserted into the card edge connector assembly 100 from a first side 102. FIGS. 9-11 show the PCB 500 being inserted into the card edge connector assembly 100 from a second side 103. In the illustrated embodiments of FIGS. 6 and 9, a first plane 550 is defined through the PCB 500 and an open socket 104 of the card edge connector assembly 100. A second plane 150 is defined through the card edge connector assembly 100, perpendicular to the first plane 550. In other words, the card edge is inserted into the open socket of the card edge connector assembly perpendicularly to the card edge connector assembly. In some embodiments, the first plane 550 and the second plane 150 may not be perpendicular, as the card edge connector assembly 100 may be designed to mate with the PCB 500 in a non-perpendicular orientation.

With reference to FIGS. 6, 7, and 8, the illustrated embodiments show a card edge connector system 1000. The card edge connector system 1000 includes a first card edge connector assembly 100. In some embodiments, the first card edge connector assembly 100 includes the card edge connector 111. The first card edge connector assembly 100 includes a card edge connector 111, further including a body 101 including a first side 102 and a second side 103, an open socket 104 extending through the body 101 from the first side 102 to the second side 103, where the open socket 104 includes an interior wall 105 and a plurality of channels 106 extending within the interior wall 105, and a plurality of electrical contacts 107 positioned within the plurality of channels 106 and extending into the open socket 104. The card edge connector system 1000 further includes a PCB 500 including a plurality of electrical pads 501 configured to electrically couple with the plurality of electrical contacts 107 of the card edge connector assembly 100, where a first end of the card edge 502 is configured to be positioned within the open socket 104 of the card edge connector assembly 100. The first card edge connector assembly 100 can include the card edge connector 111 of any one of the embodiments of the card edge connector 111 described above (i.e., any number of electrical contacts, beveled edges along the open socket perimeter, size, shape, etc.).

With continued reference to FIGS. 6, 7, and 8, the illustrated embodiments show the card edge connector 111 mated with a PCB 300. In the illustrated embodiments, the first card edge connector assembly 100 includes the card edge connector 111 and the PCB 300. In the illustrated embodiments, the PCB 500 being inserted into the open socket 104 of the card edge connector assembly 100 from the first side 102 of the card edge connector assembly 100. The PCB 500 is configured for mating with the open socket 104 of the card edge connector assembly 100.

In the illustrated embodiment, the PCB 500 includes the first end of the card edge 502. The PCB 500 is configured for the first end 502 to be positioned within the open socket 104 of the card edge connector assembly 100. In other words, the card edge is configured to fit into the open socket for electrical coupling of the card edge and the card edge connector assembly. In these embodiments, the card edge is configured to be inserted into the open socket from the top.

With reference to FIG. 6, in the illustrated embodiment, the PCB 500 includes the plurality of electrical pads 501. In some embodiments, the plurality of electrical pads 501 includes a first portion of electrical pads 506 on a first side of the card edge 504 and a second portion of electrical pads 507 on a second side of the card edge 505, wherein the second side 505 is opposite the first side 504. In some embodiments, the PCB 500 includes electrical pads 501 on one or more sides of the PCB 500. In the illustrated embodiment, the PCB 500 includes electrical pads 501 on both a first side of the card edge 504 and a second side of the card edge 505. The electrical pads 501 on the PCB 500 are configured to electrically couple with the plurality of electrical contacts 107 of the card edge connector assembly 100. In the illustrated embodiments, the electrical pads 501 are evenly spaced. In some embodiments, the electrical pads 501 may be spaced differently (i.e., further apart or in a staggered pattern). In the illustrated embodiments, the electrical pads 501 are shaped rectangularly. In some embodiments, the electrical pads 501 may be shaped differently (i.e., circular, squarely, ovular, hexagonal). In some embodiments, the PCB 500 has 2, 3, 4, 5, or more electrical pads 501. For example, in the illustrated embodiment, the PCB 500 has 12 electrical pads 501. The number of electrical pads 501 on the PCB 500 should match the number of electrical contacts 107 of the card edge connector assembly 100. In some embodiments, the number of electrical pads 501 and the number of electrical contacts 107 may not match.

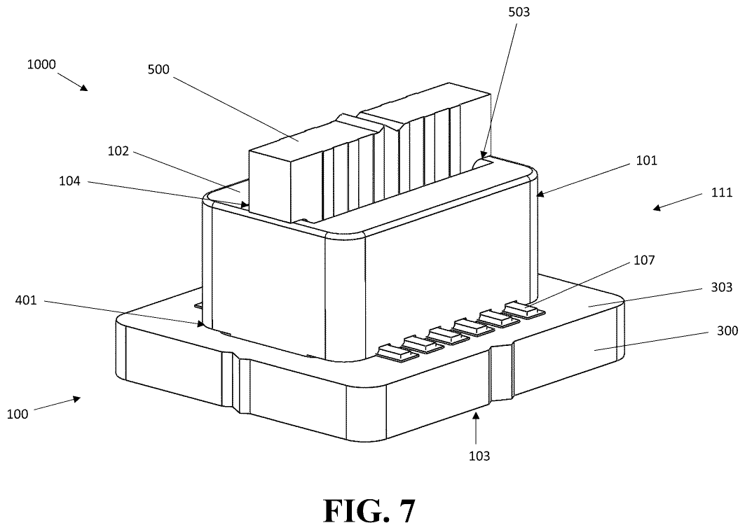

With reference to FIGS. 6 and 7, in the illustrated embodiments, the PCB 500 further includes shoulders 503. The shoulders 503 are configured to rest on the body 101 of the card edge connector assembly 100. In the illustrated embodiment of FIG. 7, the shoulders 503 rest on the first side 102 of the card edge connector assembly 100. In other words, the shoulders stop the card edge from going through the open socket of the card edge connector assembly. The shoulders are configured so only part of the card edge is inserted into the open socket for electrically coupling with the card edge connector assembly. The shoulders of the card edge rest on the surface of the body. In this embodiment, the shoulders rest on the first side.

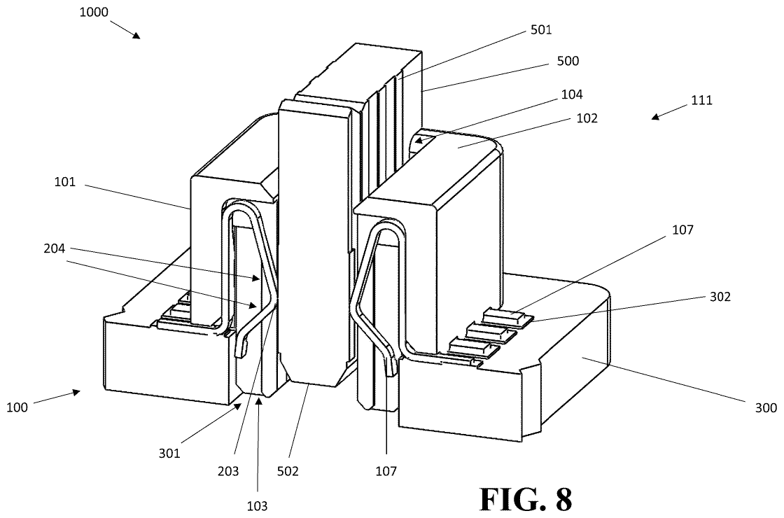

With reference to FIG. 8, the illustrated embodiment shows the mating of the PCB 500 and the card edge connector assembly 100 within the open socket 104, when the PCB 500 is inserted into the open socket 104 from the first side 102. In the illustrated embodiment, each electrical contact of the plurality of electrical contacts 107 is positioned with a contact portion 203 extending into the open socket 104. The contact portion 203 includes a contact angle 204 in a first direction toward the first side 102 of the body 101, and a contact angle 204 in a second direction toward the second side 103 of the body 101. In the illustrated embodiment, the PCB 500 is electrically coupled to the card edge connector assembly 100. The electrical pads on the card edge 501 mate with the electrical contacts 107 within the open socket 104. In some embodiments, the electrical pads on the card edge 501 mate with the contact portion 203 of the electrical contacts 107. In the illustrated embodiment, the electrical pads on the card edge 501 mate with the electrical contacts 107 in the first direction. The contact angle 204 in the first direction facilitates the mating of the electrical pads 501 and the electrical contacts 107. In the illustrated embodiment, each of the electrical pads on the card edge 501 are mated with the electrical contacts 107. In some embodiments, only some of the electrical pads 501 are mated with the electrical contacts 107. In the illustrated embodiment, each of the electrical contacts 107 are mated with the electrical pads on the card edge 501. In some embodiments, only some of the electrical contacts 107 are mated with the electrical pads on the card edge 501.

With reference to FIGS. 7 and 8, in the illustrated embodiments, the PCB 500 is electrically coupled to the PCB 300 through the electrical contacts 107 of the card edge connector assembly 100. In the illustrated embodiments, the card edge connector system 1000 includes the card edge connector assembly 100, where the card edge connector assembly 100 includes the card edge connector 111 and the PCB 300. The card edge connector 111 is mated to the PCB 300. The first end of the electrical contacts 201 is electrically coupled with the electrical pads 302 on the PCB 300. In some embodiments, the card edge connector 111 is not mated to a PCB 300. In these embodiments, the PCB 500 is still electrically coupled to the card edge connector 111. In the illustrated embodiments, the PCB 500 is inserted into the open socket 104 of the card edge connector assembly 100 from the first side 102. The PCB 500 is mated with the contact portion 203 of the electrical contacts 107 within the open socket. In the illustrated embodiments, the electrical pads on the card edge 501 are electrically coupled to the electrical contacts 107.

With continued reference to FIGS. 7 and 8, in the illustrated embodiment, the PCB 300 further includes a hole 301 configured to receive the body 101 of the card edge connector 111. The body 101 of the card edge connector 111 is partially positioned within the hole 301 of the PCB 300. In some embodiments, the body 101 of the card edge connector 111 includes shoulders 401 (see FIG. 7). The shoulders 401 are positioned adjacent to a surface of the PCB 300. In some embodiments, the shoulders 401 are positioned adjacent to a top surface 303 of the PCB 300 while at least part of the body 101 is positioned within the hole 301 of the PCB 300.

With reference to FIGS. 9, 10, and 11, the illustrated embodiments show a card edge connector system 1000, where a PCB 500 is inserted into the card edge connector assembly 100 from the bottom. In the illustrated embodiments, the card edge connector system 1000 includes a first card edge connector assembly 100. In the illustrated embodiments the first card edge connector assembly 100 includes a card edge connector 111. The card edge connector 111, including a body 101 including a first side 102 and a second side 103, an open socket 104 extending through the body 101 from the first side 102 to the second side 103, where the open socket 104 includes an interior wall 105 and a plurality of channels 106 extending within the interior wall 105, and a plurality of electrical contacts 107 positioned within the plurality of channels 106 and extending into the open socket 104. The card edge connector system 1000 further includes the PCB 500 including a plurality of electrical pads 501 configured to electrically couple with the plurality of electrical contacts 107 of the card edge connector 100, where a first end of the card edge 502 is configured to be positioned within the open socket 104 of the card edge connector assembly 100. The first card edge connector 111 can be any one of the embodiments of the card edge connector 111 described above (i.e., any number of electrical contacts, beveled edges along the open socket perimeter, size, shape, etc.).

With continued reference to FIGS. 9, 10, and 11, the illustrated embodiments show the card edge connector 111 mated with a PCB 300. In the illustrated embodiments, the card first edge connector assembly 100 includes the card edge connector 111 and the PCB 300. In the illustrated embodiments, the PCB 500 is being inserted into the open socket 104 of the card edge connector assembly 100 from the second side 103 of the card edge connector assembly 100. The PCB 500 is configured for mating with the open socket 104 of the card edge connector assembly 100.

In the illustrated embodiment, the PCB 500 includes the first end of the card edge 502. The PCB 500 is configured for the first end 502 to be positioned within the open socket 104 of the card edge connector assembly 100. In other words, the card edge is configured to fit into the open socket for electrical coupling of the card edge and the card edge connector assembly. In these embodiments, the card edge is configured to be inserted into the open socket from the bottom.

With reference to FIG. 9, in the illustrated embodiment, the PCB 500 includes a plurality of electrical pads 501. In some embodiments, the plurality of electrical pads 501 includes a first portion of electrical pads 506 on a first side of the card edge 504 and a second portion of electrical pads 507 on a second side of the card edge 505, wherein the second side 505 is opposite the first side 504. In some embodiments, the PCB 500 includes electrical pads 501 on one or more sides of the PCB 500. In the illustrated embodiment, the PCB 500 includes electrical pads 501 on both a first side of the card edge 504 and a second side of the card edge 505. The electrical pads 501 on the PCB 500 are configured to electrically couple with the plurality of electrical contacts 107 of the card edge connector assembly 100. In the illustrated embodiments, the electrical pads 501 are evenly spaced. In some embodiments, the electrical pads 501 may be spaced differently (i.e., further apart or in a staggered pattern). In the illustrated embodiments, the electrical pads 501 are shaped rectangularly. In some embodiments, the electrical pads 501 may be shaped differently (i.e., circular, squarely, ovular, hexagonal). In some embodiments, the PCB 500 has 2, 3, 4, 5, or more electrical pads 501. For example, in the illustrated embodiment, the PCB 500 has 12 electrical pads 501. The number of electrical pads 501 on the PCB 500 should match the number of electrical contacts 107 of the card edge connector assembly 100. In some embodiments, the number of electrical pads 501 and the number of electrical contacts 107 may not match.

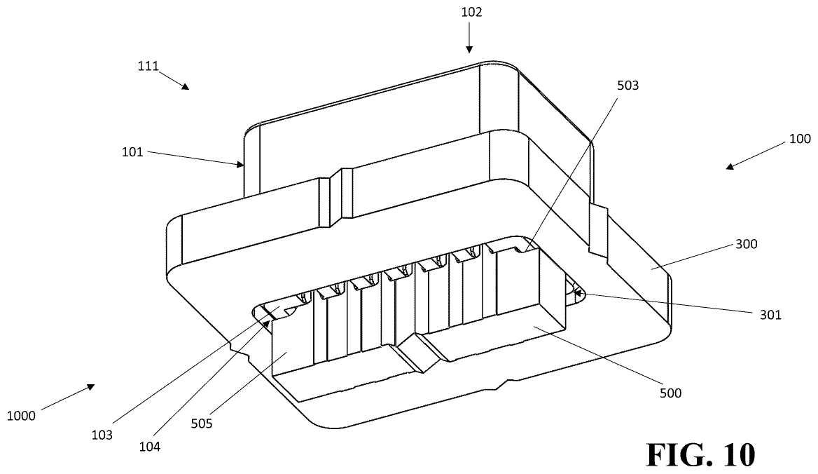

With reference to FIGS. 9 and 10, in the illustrated embodiments, the PCB 500 further includes shoulders 503. The shoulders 503 are configured to rest on the body 101 of the card edge connector assembly 100. In the illustrated embodiment of FIG. 7, the shoulders 503 rest on the second side 103 of the card edge connector assembly 100. In other words, the shoulders stop the card edge from going through the open socket of the card edge connector assembly. The shoulders are configured so only part of the card edge is inserted into the open socket for electrically coupling with the card edge connector assembly. The shoulders of the card edge rest on the surface of the body. In this embodiment, the shoulders rest on the second side.

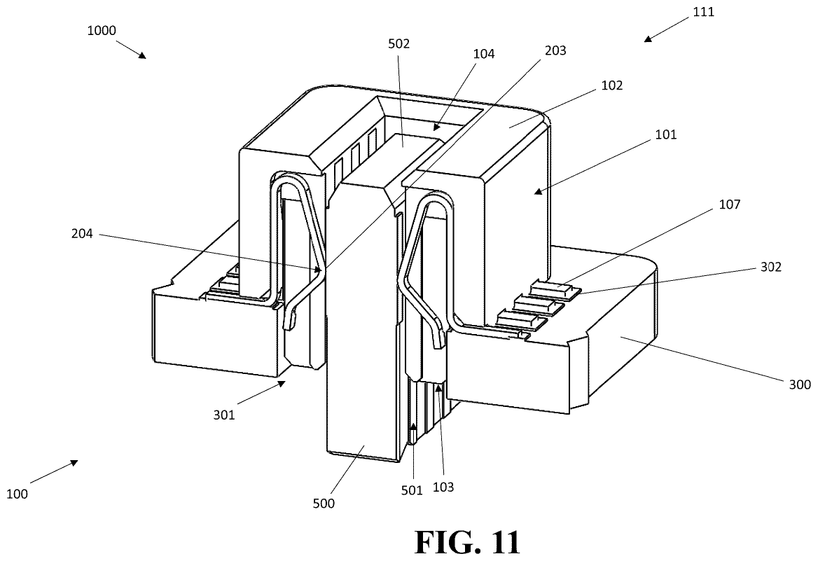

With reference to FIG. 11, the illustrated embodiment shows the mating of the PCB 500 and the card edge connector assembly 100 within the open socket 104, when the PCB 500 is inserted into the open socket 104 from the second side 103. In the illustrated embodiment, each electrical contact of the plurality of electrical contacts 107 is positioned with a contact portion 203 extending into the open socket 104. The contact portion 203 includes a contact angle 204 in a first direction, angled toward the first side 102 of the body 101, and a contact angle 204 in a second direction, angled toward the second side 103 of the body 101. In the illustrated embodiment, the PCB 500 is electrically coupled to the card edge connector assembly 100. The electrical pads on the card edge 501 mate with the electrical contacts 107 within the open socket 104. In some embodiments, the electrical pads on the card edge 501 mate with the contact portion 203 of the electrical contacts 107. In the illustrated embodiment, the electrical pads on the card edge 501 mate with the electrical contacts 107 in the second direction. The contact angle 204 in the second direction facilitates the mating of the electrical pads 501 and the electrical contacts 107. In the illustrated embodiment, each of the electrical pads on the card edge 501 are mated with the electrical contacts 107. In some embodiments, only some of the electrical pads 501 are mated with the electrical contacts 107. In the illustrated embodiment, each of the electrical contacts 107 are mated with the electrical pads on the card edge 501. In some embodiments, only some of the electrical contacts 107 are mated with the electrical pads on the card edge 501.

With reference to FIGS. 10 and 11, in the illustrated embodiments, the PCB 500 is electrically coupled to the PCB 300 through the electrical contacts 107 of the card edge connector assembly 100. In the illustrated embodiments, the card edge connector system 1000 includes a card edge connector assembly 100, where the assembly includes a PCB 300. The card edge connector 111 is mated to the PCB 300. The first end of the electrical contacts 201 is electrically coupled with the electrical pads 302 on the PCB 300. In the illustrated embodiments, the PCB 500 is inserted into the open socket 104 of the card edge connector assembly 100 from the second side 103. The PCB 500 is mated with the contact portion 203 of the electrical contacts 107 within the open socket. In the illustrated embodiments, the electrical pads on the card edge 501 are electrically coupled to the electrical contacts 107.

With continued reference to FIGS. 9 and 10, in the illustrated embodiment, the PCB 300 further includes a hole 301 configured to receive the body 101 of the card edge connector 111. The body 101 of the card edge connector 111 is partially positioned within the hole 301 of the PCB 300. In some embodiments, the body 101 of the card edge connector 111 includes shoulders 401. The shoulders 401 are positioned adjacent to a surface of the PCB 300. In some embodiments, the shoulders 401 are positioned adjacent to a top surface 303 of the PCB 300 while at least part of the body 101 is positioned within the hole 301 of the PCB 300.

With reference to FIGS. 6-11, the illustrated embodiments highlight the design flexibility the card edge connector assembly 100 provides for mating with the PCB 500. Specifically, the illustrated embodiments highlight any application where a printed circuit board needs to be mated from both directions with a card edge. In these embodiments, the PCB 500 may also be a printed circuit board (PCB). The design flexibility of the card edge connector assembly (or system) allows for optimal design choices and increased performance when using PCBs, across any industry or application. For example, if the card edge connector assembly and/or system could only be mated with the card edge from the top side, then the PCB of the card edge connector system would have a different orientation (i.e., flipping the orientation of the assembly in FIGS. 6-8). Instead, because the card edge can be inserted into the card edge connector assembly from the bottom side, the card edge connector system can remain in the same orientation. The PCB and/or card edge connector system being in a different orientation could be a suboptimal design choice, making the design more difficult to complete, more expensive to manufacture or assemble, and/or decrease performance of the PCB or card edge (or the larger system the card edge connector system and card edge may be a part of).

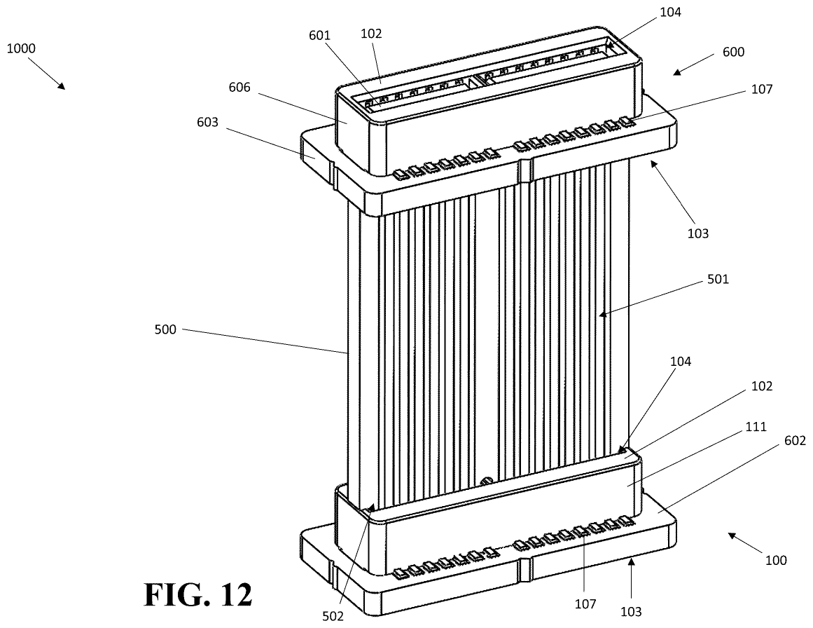

With reference to FIG. 12, the illustrated embodiment shows the card edge connector system 1000 where the system further includes a second card edge connector assembly 600 and both the first card edge connector assembly 100 and the second card edge connector assembly 600 are connected to a PCB 500. In some embodiments, the first card edge connector assembly 100 includes the first card edge connector 111 mated to a first PCB 602. The first card edge connector 111 may be any one of the embodiments of the card edge connector disclosed herein. The first card edge connector assembly 100 may also be any one of the embodiments of the card edge connector assembly disclosed herein. In some embodiments, the second card edge connector assembly 600 includes a second card edge connector 606 mated to a second PCB 603. The second card edge connector 606 may be any one of the embodiments of the card edge connector disclosed herein. The second card edge connector assembly 600 may also be any one of the embodiments of the card edge connector assembly disclosed herein. In some embodiments, the first card edge connector 111 and the second card edge connector 606 may be different embodiments of the card edge connector. The first card edge connector 111 and the second card edge connector 606 may be the same embodiment of the card edge connector. In some embodiments, the first card edge connector assembly 100 and the second card edge connector assembly 600 may be different embodiments of the card edge connector assembly. The first card edge connector assembly 100 and the second card edge connector assembly 600 may be the same embodiment of the card edge connector assembly.

With continued reference to FIG. 12, in the illustrated embodiment, the first card edge connector assembly 100 is mated with the PCB 500 where a first end of the card edge 502 is inserted into an open socket 104 of the first card edge connector assembly 100 from a first side 102. The second card edge connector assembly 600 is mated with the PCB 500 where a second end of the card edge 601 is inserted into an open socket 104 of the second card edge connector assembly 600 from a second side 103 of the card edge connector assembly. In some embodiments, the first end of the card edge 502 is inserted into the open socket 104 of the first card edge connector assembly 100 from the second side 103. In some embodiments, the second end of the card edge 601 is inserted into the open socket 104 of the second card edge connector assembly 600 from the first side 102. In some embodiments, the PCB 500 is inserted into the first card edge connector assembly 100 and the second card edge connector assembly 600 from different sides (i.e., inserting into the first side of the first card edge connector assembly and the second side of the second card edge connector assembly). In some embodiments, the PCB 500 is inserted into both the first card edge connector assembly 100 and the second card edge connector assembly 600 from the same side (i.e., both from the first side). In other words, the card edge is inserted into two card edge connector assemblies. In the illustrated embodiment, the card edge is inserted into one card edge connector assembly from the top and the other from the bottom. In some embodiments, the card edge is inserted into the two card edge connector assemblies from different directions (i.e., inserted into one from the top and the other from the bottom). In some embodiments, the card edge could be inserted into the systems from the same direction (i.e., inserted into both from the top).

With continued reference to FIG. 12, in some embodiments, the first card edge connector assembly 100 and the second card edge connector assembly 600 include a plurality of electrical contacts 107. The plurality of electrical contacts 107 extend into the open socket 104 of the first card edge connector assembly 100 and the second card edge connector assembly 600. In some embodiments, both the first end of the card edge connector assembly 502 and second end of the card edge connector assembly 600 include electrical pads 501 for mating with the plurality of electrical contacts 107 of the first card edge connector assembly 100 and the second card edge connector assembly 600.

With continued reference to FIG. 12, the card edge connector assembly provides design flexibility for mating the card edge. In the illustrated embodiment, the first PCB 602 and the second PCB 603 are mated with the PCB 500 in a perpendicular orientation, with the first and second PCBs in facing the same direction (i.e., the electrical pads on both PCBs are pointed upwards). In some embodiments, the PCBs may be mated in a different orientation with the card edge. For example, if the second card edge connector assembly could only be mated with the card edge from one direction (i.e., the top side), then the PCB of the card edge connector assembly would have a different orientation. The PCB being in a different orientation could be a suboptimal design choice, making the design more difficult to complete, more expensive to manufacture or assemble, and/or decrease performance. The illustrated embodiment highlights the flexibility the card edge connector assembly provides for mating printed circuit boards and/or card edges.

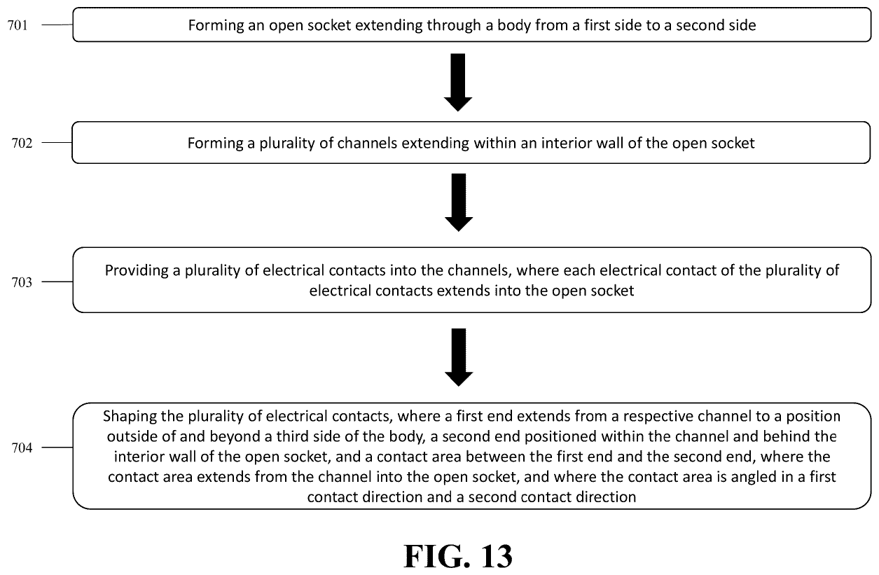

With reference to FIG. 13, an example flowchart depicting operations of a method of manufacturing a card edge connector assembly is shown. The method 700 may be used to manufacture and assemble the card edge connector 111. In some embodiments, the method 700 may include operations to manufacture and assemble the card edge connector assembly 100. In some embodiments, the method 700 entails using traditional manufacturing techniques (e.g., molding, milling, forging, thermosetting, extrusion, casting, thermoforming, stamping). In other embodiments, the method 700 entails using 3D-printing techniques. In some embodiments, the method 700 may include additional, fewer, and/or different operations. It will be appreciated what the use of a flow diagram and arrows is not meant to be limiting with respect to the order of operations or to exclude other operation which may be incorporation into the method. For example, in some embodiments, two or more of the operations of the method 700 may be performed simultaneously. In some embodiments, the operations of the method 700 may be performed in a different order.

With continued reference to FIG. 13, operation 701 includes forming an open socket 104 extending through a body 101 from a first side 102 to a second side 103. For example, the body with corresponding open socket may be formed using plastic injection molding. In another embodiment, the body may be a solid piece and the open socket may be cut out of the body by a machining process (i.e., milling). In another example, the body may be formed with the open socket removed from the body (i.e., 3D-printing the body with the open socket formed within). At operation 702, a plurality of channels 106 extending within an interior wall 105 of the open socket 104 are formed. For example, the body may be a solid piece and the channels may be cut out of the body by a machining process (i.e., milling). In another example, the body may be formed with the channels removed from the body (i.e., 3D-printing the body with the channels formed within). In other words, in some embodiments, the body is formed with the open socket at operation 701. Then, the channels may be cut out of the body. In other embodiments, operations 701 and 702 are completed simultaneously, as the body 101 may be formed with the plurality of channels 106 pre-set into the interior wall 105 of the body 101.

With continued reference to FIG. 13, at operation 703, a plurality of electrical contacts 107 are provided into the channels 106, with each electrical contact of the plurality of electrical contacts 107 extending into the open socket 104. At operation 704, the plurality of electrical contacts 107 are shaped. For example, the electrical contacts may be provided to the channels in a shape that is not a final shape of the electrical contacts during use of the card edge connector (i.e., the electrical contacts are provided to the channels as a straight piece of metal, bent to fit into the channel, and then bent into the final shape for use). The electrical contacts may be bent into the final shape after they are inserted into the channels. In some embodiments, shaping the electrical contacts 107 includes a first end 201 extends from the channel 106 to a position outside of a beyond a third side 108 of the body 101. A second end 202 is positioned within the channel 106 and behind the interior wall 105 of the open socket 104. A contact portion 203 is shaped between the first end 201 and the second end 202. The contact portion 203 extends from the channel 106 into the open socket 104, and the contact portion 203 is angled in a first direction and a second direction. For example, the first direction is angled toward the first side 102 of the body 101 and the second direction is angled toward the second side 103 of the body 101. In some embodiments, operations 703 and 704 include each electrical contact of the plurality of electrical contacts 107 being pre-shaped upon being provided to the channels 106 of the body 101. In some embodiments, operations 703 and 704 are performed simultaneously, as each electrical contact of the plurality of electrical contacts 107 are shaped while being provided into the channels 106. In other words, the method 700 outlines the manufacturing and assembly of the card edge connector assembly, where the body is formed with the open socket, and the channels are cut-out of the interior walls of the body for the electrical contacts to be inserted and shaped for mating at the first end and/or within the open socket at the contact portion.

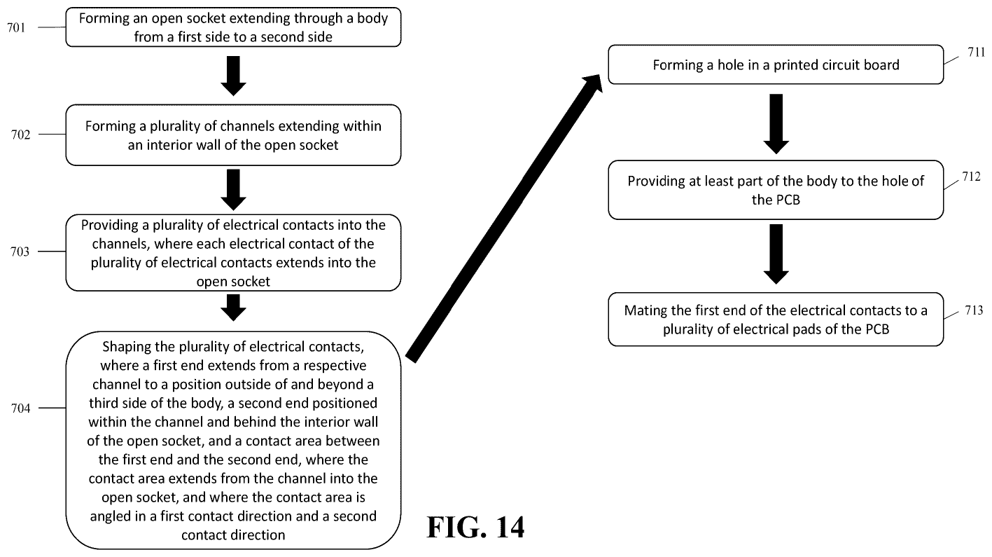

With reference to FIG. 14, an example flowchart outlining operations of a method of manufacture for the card edge connector assembly is shown. In some embodiments, the card edge connector 111 is mated with a PCB 300, assembling the card edge connector assembly 100. The PCB 300 includes electrical pads 302 for mating with the card edge connector 111. In these embodiments, the method 700 further includes operations 711-713. At operation 711, a hole 301 is formed in the PCB 300. The hole 301 is configured to receive the body 101 of the card edge connector 111. For example, the PCB may be manufactured with the hole formed in the PCB. In another example, the PCB may be a solid piece and the hole may be cut out of the PCB.

With continued reference to FIG. 14, at operation 712, at least part of the body 101 of the card edge connector 111 is provided to the hole 301. In some embodiments, the body 101 includes shoulders 401, where the shoulders 401 rest on a surface of the PCB 300 when the body 101 is provided to the hole 301 of the PCB 300. In these embodiments, part of the body 101 extends into the hole 301. For example, the body may be T-shaped (see FIG. 1), with a wider section of the body on top, and a narrower section of the body on bottom, so the narrow section extends into the hole of the PCB, and the wider section of the body rests on a surface of the PCB.

With continued reference to FIG. 14, at operation 713, each electrical contact of the plurality of electrical contacts 107 are mated with the electrical pads 302 of the PCB 300. The first end 201 of each electrical contact of the plurality of electrical contacts 107 is mated to the electrical pads 302 of the PCB 300 to electrically couple the card edge connector 111 to the PCB 300. The electrical contacts 107 may be mated to the electrical pads 302 by soldering. In some embodiments, other mating techniques are used (i.e., fastening, using adhesives, etc.). Operations 711-713 outline the assembly of the card edge connector assembly 100 when the card edge connector 111 is mated with a PCB 300. The card edge connector 111 becomes electrically coupled to the PCB 300, through the electrical contacts 107 of the card edge connector 111 and the electrical pads 302 of the PCB 300. For example, each electrical contact of the plurality of electrical contacts 107 may be soldered to the electrical pads 302 of the PCB 300. In some embodiments, other methods of mating the electrical contacts 107 and the electrical pads may be used for electrical coupling.

With reference to FIGS. 1-14, in the illustrated embodiments, the body 101 of the card edge connector 111 is made from an electrically non-conductive material. In some embodiments, the body 101 is made from plastic. The body 101 may be formed from a single piece of material or may be formed from several pieces of material assembled together. In some embodiments, the body 101 is formed using traditional manufacturing techniques (i.e., molding, milling, forging, thermosetting, extrusion, casting, thermoforming, stamping). In other embodiments, the body 101 is formed using 3D-printing techniques.

With continued reference to FIGS. 1-14, in the illustrated embodiments, the electrical contacts 107 are made of an electrically conductive material. In some embodiments, the electrical contacts 107 are made of a conductive metal. In the illustrated embodiments, the electrical pads 302 on the PCB 300 are made from an electrically conductive material. In some embodiments, the electrical pads 302 are made of a conductive metal. In the illustrated embodiments, the electrical pads 501 on the PCB 500 are made from an electrically conductive material. In some embodiments, the electrical pads 501 are made of a conductive metal. Examples of common conductive metals used in electrical components are: copper, nickel, silver, aluminum, gold, steel, brass, or an alloy thereof.

In some embodiments, the electrical contacts 107 are formed by molding, bending, cutting, or otherwise deforming the conductive material. In some embodiments, the plurality of electrical contacts 107 may be formed from a single piece of conductive material. In other embodiments, the electrical contacts 107 may be formed from different pieces of conductive material. In some embodiments, the electrical contacts 107 are flexible. The electrical contacts 107 may flex when mated with the PCB 500. Characteristics of the electrical contacts (i.e., material, size) may vary depending on the application.

With continued reference to FIGS. 1-14, in the illustrated embodiments, the PCB 300 and the PCB 500 are made of multiple materials. As stated above, the electrical pads of both the PCB and the card edge are typically made from an electrically conductive material. The outer layer (i.e., surface) or the PCB or card edge is typically made from an electrically non-conductive material. In some embodiments, he PCB and the card edge may be a commonly used circuit board type, such as a single-sided PCB, double sided PCB, multi-layer PCB, etc. In some embodiments, the PCB 500 is also a printed circuit board. The PCB or the card edge may include a variety of components, such as resistors, capacitors, inductors, transistors, etc. The PCB and the card edge may be rigid or flexible. Characteristics of the PCB and the card edge (i.e., size, material, components) may vary depending on the application.

Notwithstanding the embodiments described above in reference to FIGS. 1-14, various modifications and inclusions to those embodiments are contemplated and considered within the scope of the present disclosure.

As utilized herein with respect to numerical ranges, the terms “approximately,” “about,” “substantially,” and similar terms generally mean+/−10% of the disclosed values, unless specified otherwise. As utilized herein with respect to structural features (e.g., to describe shape, size, orientation, direction, relative position, etc.), the terms “approximately,” “about,” “substantially,” and similar terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A card edge connector, comprising:
a body including a first side and a second side;
an open socket extending through the body from the first side to the second side;
wherein the open socket includes an interior wall and a plurality of channels extending within the interior wall; and
a plurality of electrical contacts positioned within the plurality of channels and extending into the open socket.

2. The card edge connector of claim 1, wherein each electrical contact of the plurality of electrical contacts comprises:
a first end extending from a respective channel to a position outside of and beyond a third side of the body;
a second end positioned within the channel and behind the interior wall of the open socket; and
a contact portion between the first end and the second end, wherein the contact portion extends from the channel into the open socket.

3. The card edge connector of claim 2, wherein each electrical contact of the plurality of electrical contacts comprises:
a U-shaped portion between the contact portion and the first end;
a leg portion extending between the U-shaped portion and the first end, wherein the first end extends perpendicularly from the leg portion;
wherein the contact portion comprises a bent portion connecting a first contact section extending between the second end and the contact portion and a second contact section extending between the contact portion and the U-shaped portion.

4. The card edge connector of claim 1, wherein each electrical contact of the plurality of electrical contacts comprises a contact portion extending into the open socket, wherein the contact portion includes a first portion extending at a first angle in a first contact direction toward the first side of the body, and a second portion extending at a second angle in a second contact direction toward the second side of the body.

5. The card edge connector of claim 1, wherein the plurality of electrical contracts are configured to electrically coupled to a plurality of electrical pads of a printed circuit board (PCB), wherein the PCB comprises a hole configured to receive the body.

6. The card edge connector of claim 5, wherein the body further comprises shoulders, and wherein the shoulders are configured to be positioned adjacent to a surface of the PCB and to the hole of the PCB.

7. The card edge connector of claim 5, wherein each electrical contact of the plurality of electrical contacts comprises a first end extending from a respective channel to a position outside of and beyond a third side of the body, and wherein the first ends of the plurality of electrical contacts are configured to be electrically coupled to the electrical pads of the PCB.

8. The card edge connector of claim 1, wherein the body includes beveled edges on both the first side and the second side, and wherein each of the beveled edges extend along a perimeter of the open socket.

9. A card edge connector system, comprising:
a first card edge connector, comprising:
a body including a first side and a second side;
an open socket extending through the body from the first side to the second side;
wherein the open socket includes an interior wall and a plurality of channels extending within the interior wall; and
a plurality of electrical contacts positioned within the plurality of channels and extending into the open socket; and
a first printed circuit board (PCB), wherein the first PCB comprises a hole configured to receive the body.

10. The card edge connector system of claim 9, wherein each electrical contact of the plurality of electrical contacts is positioned with a contact portion extended into the open socket, wherein the contact portion includes a contact angle in a first contact direction, angled toward the first side of the body, and a contact angle in a second contact direction, angled toward the second side of the body.

11. The card edge connector system of claim 9, further comprising a second PCB comprising a plurality of electrical pads configured to electrically couple with the plurality of electrical contacts of the card edge connector assembly, wherein a first end of the second PCB is configured to be positioned within the open socket of the card edge connector assembly.

12. The card edge connector system of claim 11, wherein the plurality of electrical pads of the second PCB electrically couple to the contact portion of the electrical contacts positioned within the open socket.

13. The card edge connector system of claim 11, wherein the second PCB further comprises shoulders, and wherein the shoulders are positioned adjacent to a surface of the card edge connector.

14. The card edge connector system of claim 11, further comprising a second card edge connector assembly, and wherein the first end of the second PCB is configured to be positioned within the open socket of the card edge connector assembly and a second end of the second PCB is configured to be positioned within an open socket of the second card edge connector assembly.

15. The card edge connector system of claim 9, wherein the plurality of electrical pads comprises a first portion of electrical pads on a first side of the second PCB and a second portion of electrical pads on a second side of the second PCB, wherein the second side is opposite the first side.

16. The card edge connector system of claim 9, wherein the body further comprises shoulders, and wherein the shoulders are positioned adjacent to a surface of the first PCB.

17. The card edge connector system of claim 9, wherein the first PCB further comprises electrical pads configured to electrically couple with the first ends of the plurality of electrical contacts.

18. The card edge connector system of claim 9, wherein the body includes beveled edges on both the first side and the second side, and wherein each of the beveled edges extend along a perimeter of the open socket.

19. A method for creating a card edge connector assembly, comprising:
forming an open socket extending through a body from a first side to a second side;
forming a plurality of channels extending within an interior wall of the open socket;
providing a plurality of electrical contacts into the channels, wherein each electrical contact of the plurality of electrical contacts extends into the open socket; and
shaping each electrical contact of the plurality of electrical contacts, wherein a first end extends from a respective channel to a position outside of and beyond a third side of the body, a second end positioned within the channel and behind the interior wall of the open socket, and a contact portion between the first end and the second end, wherein the contact portion extends from the channel into the open socket, and wherein the contact portion is angled in a first contact direction and a second contact direction.

20. The method for creating a card edge connector assembly of claim 19, wherein the method further comprises:
forming a hole in a printed circuit board (PCB);
providing at least part of the body to the hole of the PCB; and
mating the first end of each of the plurality of electrical contacts to a plurality of electrical pads of the printed circuit board.
